(19) United States
(12) Patent Application Publication
(10) Pub. No.: US 2026/0098902 A1
(43) Pub. Date: Apr. 9, 2026

(54) CELL FIXTURE ASSEMBLY AND METHOD OF USING THE SAME

(71) Applicant: SOLITHOR BV, Sint-Truiden (BE)

(72) Inventors: Walid ALKARMO, Limont (BE); Rjais MINYAEV, Liège (BE); Fanny BARDÉ, Amiens (FR)

(21) Appl. No.: 19/115,044

(22) PCT Filed: Sep. 26, 2023
(86) PCT No.: PCT/EP2023/076465

§ 371 Date: Mar. 25, 2025

(30) Foreign Application Priority Data
Sep. 26, 2022 (EP) 22197681.4

(51) Int. Cl. G01R 31/36

(52) U.S. Cl. CPC G01R 31/3644

(57) ABSTRACT

The technology of the present invention generally relates to the field of battery technology, and more particularly relates to a cell fixture assembly for testing of a single electrochemical cell or a number of electrochemical cells stacked on top of each other, wherein the cell fixture assembly comprises at least one cell fixture and a base station; wherein the cell fixture comprises: at least one fixed base plate; at least two moveable plates arranged parallel to the base plate; whereby the moveable plates have oppositely arranged surfaces for contacting the electrochemical cell mounted between them; whereby the fixed and moveable plates comprise a plurality of apertures that are at least partially aligned to create a plurality of vertical channels that extend through said plates; a pressure sensor means, disposed between the base plate and at least one of the moveable plates, comprising a sensor member arranged to support said moveable plate, and configured for measuring a pressure applied to the electrochemical cells; a plurality of rotatable rods, insertable in the plurality of vertical channels, that are configured to rotatably couple with at least one of the moveable plates; whereby a rotation of the plurality of rotatable rods causes one of the moveable plates to move relative to the other moveable plate, thereby clamping or releasing the electrochemical cell mounted between them; and, a plurality of coupling members in connection with the plurality of rotatable rods; wherein the base station comprises: a plurality of actuators configured for releasably coupling with the plurality of coupling members of the cell fixture, and for inducing the rotation of the rotatable rods, and —at least one motor configured for driving the actuators.

### FIELD OF THE INVENTION

The technology of the present invention generally relates to the field of electrochemical batteries, and more particularly relates to a fixture for testing of one or more electrochemical cells, for example, a single electrochemical cell or any number of electrochemical cells stacked on top of each other, and an assembly comprising said cell test fixture and a base station.

### BACKGROUND

Electrochemical battery packs find widespread use in various transport applications, ranging from automotive to aviation, marine to space. These battery packs typically comprise numerous electrochemical cells arranged either in parallel or in series, enclosed within an outer protective casing. Each individual cell functions as an independent battery, with its negative electrode (anode) linked to a negative terminal and its positive electrode (cathode) connected to a positive terminal. These individual cells can be composed of various stacks, each consisting of an anode, electrolyte, and cathode.

When assembled into a battery pack, there is inevitably surface pressure between the cells. This mechanical compression can impact the capacity, open-circuit voltage, and internal resistance of both fresh and aged electrochemical cells. Prior to assembly, it is important to investigate the performance and aging of cells under pressure to enhance quality and safety. For instance, numerous studies suggest that applying the right amount of compressive pressure to the cells can extend the cycle life of a cell compared to a non-compressed cell.

In commonly used research setups, a test cell is mechanically secured between a pair of plates by tightening several screws with a torque wrench. However, this setup often results in an uneven pressure distribution on the test cell's surface. Consequently, the fixture plates may locally bend, leading to torsion or twisting. Such localized deformation compromises the reliability, reproducibility, and accuracy of the measurements.

Alternative cell fixture setups exist that are capable of applying a more uniform pressure distribution by sandwiching a test cell between a pair of actuated (e.g., pneumatic) press plates. However, these systems tend to be mechanically complex, expensive, and limit the number of cells that can be tested simultaneously with a single press system. Furthermore, the cell must remain securely fixed between the press plates to maintain the applied pressure during electrochemical characterizations, making it impractical for testing purposes when different testing conditions are required, such as changes in temperature.

Accordingly, there is a need for an improved method and apparatus to mechanically secure one or more electrochemical cells while reliably maintaining a compressive pressure when subjecting them to various testing conditions.

### SUMMARY OF THE INVENTION

The technology of the present invention generally relates to the field of electrochemical batteries, and more particularly relates to a fixture for testing an electrochemical cell, an assembly comprising said cell test fixture, and to a method for using the same.

Reliable testing of a clamped cell, under pressure, is key for electrochemical characterisation, planning, error detection, quality assurance, among other operating factors. It is, therefore, an objective of the present invention to improve the consistency of such measurements by precisely applying a compressive pressure on one or more electrochemical cells and reliably maintaining it under different testing conditions. Accordingly, a cell test fixture is disclosed herein, that is moveable and interactable while the cell remains clamped, allowing for the application of different testing conditions, optionally at different testing locations, which is compatible with a number of different testing tools.

It is a further objective of the present invention to apply the compressive pressure more homogeneously and uniformly across the electrochemical cells compared to existing cell fixtures. The more homogenous pressure distribution can provide an improvement in performance and safety of the clamped cell, and further extend the battery life.

Furthermore, reliably applying the compressive pressure at a desired magnitude is critical to ensure the accuracy and reliability of the cell fixtures. Therefore, another objective of the present invention is to enhance the accuracy and reliability of applying compressive pressure while maintaining user-friendliness. Accordingly, a base station is disclosed herein that can be releasably coupled to the cell fixture to controllably apply or release the compressive and advantageously homogeneous pressure (automatically) to one or more electrochemical cells mounted in the cell fixture, and subsequently, it can release the cell fixture without altering the compressive pressure applied to the electrochemical cells and without the need for additional fasteners, such as nuts or similar components. The coupling and releasing of the electrochemical cells from the base station are advantageously performed in a user-friendly manner that does not require complex interactions or strenuous manual labour.

Yet another objective of the present invention is to enhance the versatility of the base station, particularly when used in combination with a plurality of cell fixtures of varying dimensions or different configuration, such as the inclusion of different sensors mounted on the cell fixture. Accordingly, in accordance with one or more embodiments, the base station may be configured for adaptability to different configurations of the cell fixture, thereby accommodating various dimensions that align with the size, dimensions and quantity of electrochemical cells across a wide range of applications and testing conditions. This adaptability makes it well-suited for applications such as laboratory testing or shared production floor use, where rapid throughput is desired.

An aspect of the present invention relates to a cell fixture for use in combination with a base station, that is configured for applying and retaining of a compressive pressure on one or more electrochemical cells, the cell fixture comprising
at least one fixed base plate;
at least two moveable plates arranged in parallel relation to the base plate; whereby the moveable plates have oppositely arranged surfaces configured for clamping of the cell mounted between them; whereby the fixed and moveable plates comprise a plurality of apertures that are at least partially aligned to form a plurality of vertical channels that extend through said plates;
a plurality of rotatable rods, insertable in the plurality of vertical channels, that are configured to rotatably couple with at least one moveable plate; whereby a rotation of said plurality of rotatable rods causes said moveable plate to move relative to the other moveable plate, thereby clamping the cell mounted between them;
a plurality of coupling members configured for releasably coupling the plurality of rotatable rods with the base station;
a pressure sensor means, mountable between the base plate and at least one moveable plate, comprising a sensor member arranged to support a moveable plate and configured for measuring a pressure applied onto the cell.

In some embodiments the apertures of at least one moveable plate are threaded, and the plurality of rotatable rods have a threaded portion, complementary to the threaded apertures of said moveable plate; preferably whereby the plurality of rods is insertable in the plurality of vertical channels in such a way that their threaded portions rotatably couple with the threaded apertures of the moveable plate.

In some embodiments the coupling member is arranged on an end of the rotatable rod, which preferably extends from the base plate.

In some embodiments the coupling member comprises a receptacle arranged on an end of the rotatable rod, with a fitting that matches an actuator of the base station such that at least a portion of said actuator can be inserted into said coupling member.

In some embodiments the cell fixture comprises an electrode connector means that comprises a pair of contact pins, arranged on one side of a moveable plate, that are configured for electrically contacting an electrode of the cell, and a pair of electrical connectors, arranged on the opposite side of said moveable plate, that are electrically connected to said contact pins.

In some embodiments, the pair of contact pins have a contact distance between them that is adjustable to match the dimension of the electrodes and/or cell tabs; preferably adjustable in a direction defined along the length of the moveable plate that the electrode connector means is arranged on, and/or adjustable in another direction relative to the moveable plate that the electrochemical cell can be mounted on.

In some embodiments the moveable plate supported by the pressure sensor means is configured to prevent coupling with the threaded portions of the plurality of rotatable rods.

In some embodiments the plurality of rotatable rods has a nonthreaded portion, corresponding with the position of the moveable plate supported by the pressure sensor.

In some embodiments the cell fixture comprises an expansion sensor means configured for measuring an expansion of the cell, preferably comprising a displacement sensor configured for measuring a distance between at least one moveable plate and at least one fixed plate.

In some embodiments the cell fixture comprises a second fixed plate arranged in parallel relation to the base plate, at an opposite end of the plurality of rods; and a biasing member configured for biasing said fixed plate away from at least one moveable plate such that said fixed plate remains in a fixed position relative thereto; and an expansion sensor means configured for measuring a distance between said second fixed plate and said moveable plate.

In some embodiments the expansion sensor means comprises a displacement sensor, arranged between the second fixed plate and said moveable plate and configured for contacting at least one moveable plate; preferably mounted in an aperture provided in said fixed plate.

In some embodiments at least one moveable plate is configured for electrically insulating the cell; preferably wherein at least one moveable plate is covered by an electrically insulating coating or comprises an electrically insulating material mounted thereon.

An aspect of the present invention relates to a cell fixture assembly for applying and retaining of a compressive pressure on one or more electrochemical cells, the cell fixture assembly comprising
the cell fixture as described in the present invention, and
a base station comprising a plurality of actuators configured for releasably coupling with a plurality of coupling members of said cell fixture, and at least one motor configured for driving said actuators to rotate the plurality of rods of the cell fixture, such that their rotation causes at least one moveable plate to move relative to the other moveable plate, thereby clamping the cell mounted between them.

In some embodiments the cell fixture is mountable on the base station such that it can freely switch between a coupled state and a released state without changing the compressive pressure applied onto the cell.

An aspect of the present invention relates to a cell fixture assembly for applying and retaining a compressive pressure on one or more electrochemical cells; wherein the cell fixture assembly comprises at least one cell fixture and a base station;

wherein the cell fixture comprises:
at least one fixed base plate;
at least two moveable plates arranged parallel to the base plate; whereby the moveable plates have oppositely arranged surfaces for contacting the electrochemical cell mounted between them; whereby the fixed and moveable plates comprise a plurality of apertures that are at least partially aligned to create a plurality of vertical channels that extend through said plates;
a pressure sensor means, disposed between the base plate and at least one of the moveable plates, comprising a sensor member arranged to support said moveable plate, and configured for measuring a pressure applied to the electrochemical cells;
a plurality of rotatable rods, insertable in the plurality of vertical channels, that are configured to rotatably couple with at least one of the moveable plates; whereby a rotation of the plurality of rotatable rods causes one of the moveable plates to move relative to the other moveable plate, thereby clamping or releasing the electrochemical cell mounted between them; and,
a plurality of coupling members in connection with the plurality of rotatable rods;
   wherein the base station comprises:
a plurality of actuators configured for releasably coupling with the plurality of coupling members of the cell fixture, and for inducing the rotation of the rotatable rods, and
at least one motor configured for driving the actuators.

In some embodiments the base station comprises a plurality of motors configured for driving each actuators independently.

In some embodiments whereby the plurality of actuators and/or motors are moveably arranged such that their position can be adjusted along at least one axis of movement to match the position of a corresponding coupling member of the cell fixture.

In some embodiments whereby the plurality of actuators and/or motors are moveably arranged such that their position can be adjusted along at least one axis of movement to match the dimension of the cell fixture; preferably by adjusting the base station's mounting position to a plurality of cell fixture sizes.

In some embodiments the plurality of actuators and/or motors are moveably coupled such that move simultaneously along the surface of the base station, preferably in opposite directions.

In some embodiments the plurality of actuators and/or motors are moveably coupled such that their position is adjusted simultaneously, preferably in opposite directions.

In some embodiments the motor comprises a stepper motor configured for rotating at least one rod in a number of predefined steps; preferably dividing a full rod rotation into steps of 5 nm or less.

In some embodiments the press station comprises a control unit communicatively connected to the pressure sensor means to receive pressure sensing data therefrom; whereby the control unit is operatively connected to the at least one motor and configured for controlling the actuation of at least one actuator based on a said sensing data; preferably to apply a pressure onto the cell based on user input.

In some embodiments the press station comprises a control unit configured to receive pressure sensing data from the pressure sensor means, and configured for controlling the actuation of the actuator in order to apply a selected pressure onto the cell based on a user input.

In some embodiment, a plurality of electrochemical cells are stacked on top of each other on the moveable plate of the cell fixture.

Another aspect of the present invention relates to a cell fixture for use or when used in combination with a base station of a cell fixture assembly as described herein; wherein the cell fixture comprises: at least one fixed base plate; at least two moveable plates arranged parallel to the base plate; whereby the moveable plates have oppositely arranged surfaces for contacting the electrochemical cell mounted between them; whereby the fixed and moveable plates comprise a plurality of apertures that are at least partially aligned to create a plurality of vertical channels that extend through said plates; a pressure sensor means, disposed between the base plate and at least one of the moveable plates, comprising a sensor member arranged to support said moveable plate, and configured for measuring a pressure applied to the electrochemical cell; a plurality of rotatable rods, insertable in the plurality of vertical channels, that are configured to rotatably couple with at least one of the moveable plates; whereby a rotation of the plurality of rotatable rods causes one of the moveable plates to move relative to the other moveable plate), thereby applying or releasing compressive pressure on the electrochemical cell mounted between them; and, a plurality of coupling members in connection with the plurality of rotatable rods, that are configured for releasably coupling with a plurality of rotatable rods of the base station.

Another aspect of the present invention relates a base station for use or when used in combination with one or more cell fixtures of the cell fixture assembly a cell fixture assembly as described herein; wherein the base station comprises: a plurality of actuators configured for releasably coupling with a plurality of coupling members of the cell fixture, and for inducing the rotation of the rotatable rods, and at least one motor configured for driving the actuators.

Another aspect of the present invention relates to a method for applying and retaining a compressive pressure, preferably as a compressive pressure, on an electrochemical cell by using the fixture assembly as described in the present invention; the method comprising the steps of
mounting a cell fixture onto a base station by releasably coupling a plurality of coupling members of the cell fixture to a plurality of actuators of the base station;
mounting the electrochemical cell on a moveable plate of the cell fixture;
driving an actuator of the base station to induce a rotation of a plurality of rods of the cell fixture such that at least one moveable plate moves towards another moveable plate, thereby applying or releasing compressive pressure on the one or more cells mounted between them;
releasing the cell fixture from said base station without altering the compressive pressure applied on the electrochemical cell.

### DESCRIPTION OF THE FIGURES

The following description of the figures relate to specific embodiments of the disclosure which are exemplary in nature and not intended to limit the teachings or applications of the present invention.

Throughout the drawings, the corresponding reference numerals indicate the following parts and features: cell fixture (1); base plate (11); supported plate (12); coupled plate (13); fixed plate (14); aperture (15); central aperture (16); rotatable rod (2); friction reducing means (21); biasing means (22); coupling member (3); electrochemical cell (4); electrically insulating cover (5); pressure sensor means (6); sensor member (61); sensor connector socket (62); electrode connector means (7); electrical contacts (71); electrical connectors (72); expansion sensor means (8); base station (9); actuator (91); motor (92); user interface (94); display (95); shield (96); cell fixture assembly (100).

FIG. 1 shows an embodiment of a cell fixture assembly comprising a cell fixture 1 mountable on a base station 9.

FIG. 2 shows an embodiment of a cell fixture 1 from a perspective view.

FIG. 3 shows the cell fixture 1 of FIG. 2 from a side view.

FIG. 4 shows the cell fixture 1 of FIG. 2 from a front view.

FIG. 5 shows another embodiment of a cell fixture 1 from a perspective view.

FIG. 6 shows the cell fixture 1 of FIG. 5 from a side view.

FIG. 7 shows the cell fixture 1 of FIG. 5 from a front view.

FIG. 8 shows an embodiment of a base station 9 from a perspective view.

FIG. 9 shows an exemplary actuator 91 and motor 92 suitable for the base station 9 of FIG. 8.

FIG. 10 shows an embodiment of a base station 9 with moveably arranged actuators 91 from a top view.

FIG. 11 shows another embodiment of a base station 9 with a cover shield 96.

FIG. 12 shows the force (N) measured within the cell fixture over time (sec). The dashed line indicates a release of the cell fixture 1 from the base station 9. Specifically, FIG. 12A shows an example for low pressure (±50 N), FIG. 12B for medium pressure (±1 000 N), and FIG. 12C for high pressure (±30 000 N).

### DETAILED DESCRIPTION

In the following detailed description, the technology underlying the present invention will be described by means of different aspects thereof. It will be readily understood that the aspects of the present invention, as generally described herein, and illustrated in the figures, can be arranged, substituted, combined, and designed in a wide variety of different configurations, all of which are explicitly contemplated and make part of this disclosure. This description is meant to aid the reader in understanding the technological concepts more easily, but it is not meant to limit the scope of the present invention, which is limited only by the claims.

Specifically, the present disclosure relates to technology enabling the application and maintenance of a compressive pressure on one or more electrochemical cells, more particularly the present invention relates to a cell fixture assembly, and to a method for using the same. As used herein, an “electrochemical cell” refers to a device that converts chemical energy into electrical energy or vice versa by facilitating chemical reactions through the movement of electrons between two electrodes immersed in an electrolyte solution. It serves as the fundamental unit in batteries, fuel cells, and various electrochemical processes.

The technology of the present invention can be considered ‘general purpose’ technology in the sense that it can be readily adapted for testing of a variety of different electrochemical cells. This includes, for example, liquid-state and solid-state electrochemistry, which may be implemented in various battery applications, such as those used in automotive, aviation, marine, space, or similar industries.

An overview of various aspects of the technology of the present invention is given hereinbelow, after which specific embodiments will be described in more detail. This overview is meant to aid the reader in understanding the technological concepts more quickly, but it is not meant to identify the most important or essential features thereof, nor is it meant to limit the scope of the present invention, which is limited only by the claims. When describing specific embodiments, reference is made to the accompanying drawings, which are provided solely to aid in the understanding of the described embodiment.

An aspect of the present invention relates to a cell fixture assembly for applying and mainting a compressive pressure on one or more electrochemical cells; wherein the cell fixture assembly comprises at least one cell fixture and a base station;

wherein the cell fixture comprises:
at least one fixed base plate;
at least two moveable plates arranged parallel to the base plate; whereby the moveable plates have oppositely arranged surfaces for contacting the electrochemical cell mounted between them; whereby the fixed and moveable plates comprise a plurality of apertures that are at least partially aligned to create a plurality of vertical channels that extend through said plates;
a pressure sensor means, disposed between the base plate and at least one of the moveable plates, comprising a sensor member arranged to support said moveable plate, and configured for measuring a pressure applied to the electrochemical cells;
a plurality of rotatable rods, insertable in the plurality of vertical channels, that are configured to rotatably couple with at least one of the moveable plates; whereby a rotation of the plurality of rotatable rods causes one of the moveable plates to move relative to the other moveable plate, thereby clamping or releasing the electrochemical cell mounted between them; and,
a plurality of coupling members in connection with the plurality of rotatable rods;
   wherein the base station comprises:
a plurality of actuators configured for releasably coupling with the plurality of coupling members of the cell fixture, and for inducing the rotation of the rotatable rods, and
at least one motor configured for driving the actuators.

Another aspect of the present invention relates to a cell fixture for use or when used in combination with a base station, configured for applying and retaining of a homogenous pressure distribution on one or more electrochemical cells, the cell fixture comprising
at least one fixed base plate;
at least two moveable plates arranged in parallel relation to the base plate; whereby the moveable plates have oppositely arranged surfaces configured for clamping of the cell mounted between them; whereby the fixed and moveable plates comprise a plurality of apertures that are at least partially aligned to form a plurality of vertical channels that extend through said plates; whereby the apertures of at least one moveable plate are threaded;
a plurality of rotatable rods having a threaded portion, complementary to the threaded aperture of moveable plate; whereby the plurality of rods is insertable in the plurality of vertical channels in such a way that their threaded portions couple with the threaded apertures of the moveable plate;
a plurality of coupling members configured for releasably coupling the plurality of rotatable rods with the base station;
a pressure sensor means, mountable between the base plate and at least one moveable plate, and configured for measuring a pressure applied onto the cell;

Another aspect of the present invention relates to a base station for use or when used in combination with one or more cell fixtures for applying and retaining of a homogenous pressure distribution on one or more electrochemical cells, the base station comprising:
a plurality of actuators configured for releasably coupling with a plurality of coupling members of the cell fixture, and at least one motor configured for driving said actuators to rotate the plurality of rods of the cell fixture, such that their rotation causes at least one moveable plate to move relative to the other moveable plate, thereby clamping the cell mounted between them.

Another aspect of the present invention relates to a method for applying and retaining of a homogenous pressure distribution on an electrochemical cell by using the fixture assembly as described in the present invention; the method comprising the steps of
mounting a cell fixture onto a base station by releasably coupling a plurality of coupling members of said cell fixture to a plurality of actuators of said base station;
mounting at least one electrochemical cell on a moveable plate of said cell fixture;
driving an actuator of the base station to rotate a plurality of rods of said cell fixture such that at least one moveable plate is moved towards another moveable plate, thereby applying a clamping force onto the cell mounted between them;
releasing said cell fixture from said base station without changing the pressure distribution applied onto the cell; whereby said cell fixture is preferably released without applying any fastener, such as nuts or the like.

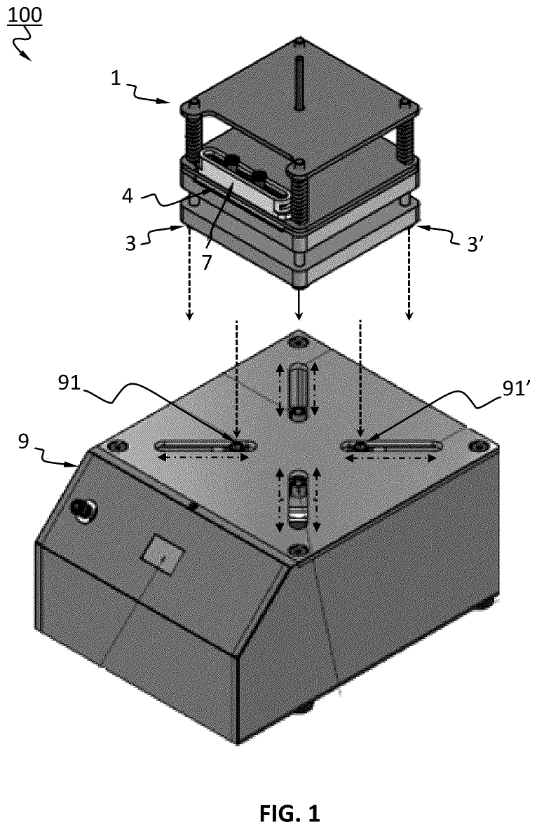

The assembly 1 of the present invention is first discussed with reference to FIG. 1, which shows an embodiment of a cell fixture 1 in a released state, decoupled from a base station 9. Specifically, the cell fixture 1 is mountable on the base station 9—indicated by the dashed arrows—such that it can freely switch between a coupled state and a released state, without changing the compressive pressure applied onto the mounted cell 4.

In the coupled state, the base station 9 is configured to interact with the cell fixture 1 to controllably adjust the pressure applied onto a cell 4 mounted in the cell fixture 1. In the released state, the cell fixture 1 is configured to maintain the pressure applied by means of the base station 9 until the cell 4 is released, advantageously by coupling with the base station 9 again. Advantageously the base station 9 may be used to couple with a plurality of different cell fixtures 1 such that it can be universally used across various testing set-ups. For example, a first cell fixture having a particular dimension can be coupled to the base station to apply a particular pressure, next this first cell fixture can be released (while the applied pressure is maintained by the fixture) from the base station so that another, e.g. second, cell fixture can be coupled to the (now free) base station in order to do the same. It may be appreciated that the other, e.g. second, cell fixture may have the same or different number of cells and/or the same or different dimensions, depending on the embodiment of the base station, as explained later.

The coupling between the cell fixture 1 and the base station 9 can be realised by one or more coupling members 3. In the shown embodiment a plurality of coupling members 3 is arranged on the underside of the cell fixture 1, which allows for easier mounting on top of the base station 9. The coupling members 3 are configured for releasable coupling, without the need for additional fasteners, such as screws, nuts, caps, or the like, commonly used in devices of the art.

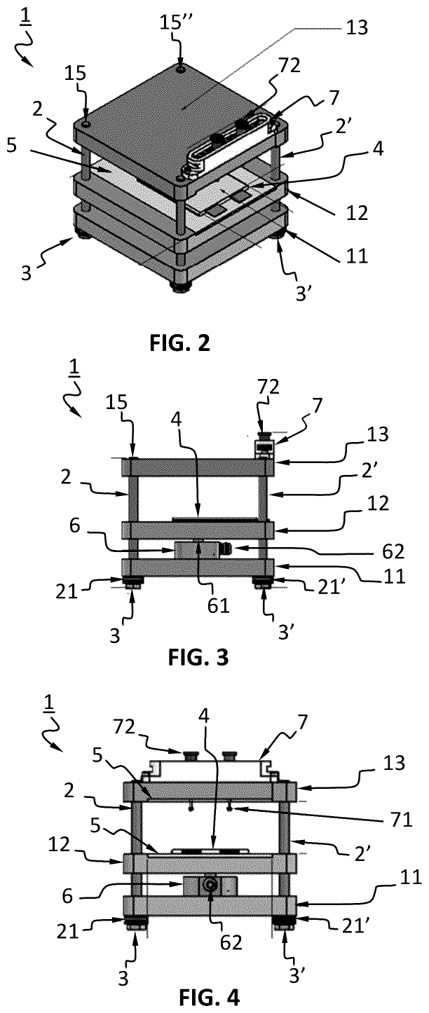

An embodiment of the cell fixture is discussed in more detail with reference to FIG. 2, which shows a fixture 1 comprising three horizontal plates arranged in parallel relation to each other. The lower plate 11 is a fixed plate which serves as a base for the fixture 1 and will be referred to hereinbelow as the “base plate”. The middle 12 and upper 13 plates are two moveable plates; their position is not fixed but can change relative to the base plate 11.

The base plate may be fixed using techniques known in the art. Preferably, the base plate is fixed without fasteners such that it cannot be loosened when the moveable plates are moved. For example, the base plate may be a tapped plate that is fixed in position by one or more components of the cell fixture, such as the coupling members.

FIG. 2 further shows that an electrochemical cell 4 can be mounted onto the upper surface of the middle plate 12, when it is spaced apart from the upper plate 13. The opposing surfaces of said plates 12-13 are accordingly configured for clamping of the cell 4 mounted between them. Specifically, the position of the upper plate 13 can be adjusted, downwards and upwards, such that a compressive pressure is applied onto the cell 4 upon contact.

In some embodiments a plurality of electrochemical cells may be mounted in the cell fixture, for example, two cells or three cells, that are advantageously stacked on top of each other between the opposing surfaces of the moveable plates. Such an arrangement allows for testing the compressive pressure onto a battery stack. Alternatively or in combination the cells may be arranged next to each other, provided that the plates are sufficiently large to cover the dimension of the cell. The cells may be electrically connected, in parallel or in series, or be separately connected for independent measurements.

For example, as shown in FIG. 3, the three plates 11-13 can be fixed onto four vertical rods 2 arranged at the corners of said plates through a number of apertures 15. Specifically, each plate can have four apertures 15 arranged at every corner thereof, and the three plates 11-13 are arranged so that their corresponding apertures are aligned, thereby forming four vertical channels, perpendicular to the horizontal plates, which the rods 2 can be inserted to. The rods 2 are sufficient long to fully extend through the vertical channels and still allow for sufficiently spacing apart the plates 11-13 such that other components can be mounted between them, such as the cell 4 and pressure sensing means 6.

The clamping of the cell is realised by implementing a different coupling for the movable plates to the rods. Specifically, the rods are rotatably fixed to the plates such that the rods can be rotated within the vertical channels formed by the apertures. The base plate's position is fixed and does not change when the rods are rotated. The middle and upper plates are moveably arranged, such that their positions can change relative to the base plate when the rods are rotated. Specifically, the supported plate is loosely moveable and supported by a member of the pressure sensing mean. Therefore, this plate is referred to hereinbelow as the “supported plate”. However, the supported moveable plate is not coupled to the rods and hence its position does not change when the rods are rotated. Lastly, the upper plate is controllably moveable and coupled to the rods such that its position can be adjusted, upwards or downwards, by rotation of the rods. Therefore, this plate is referred to hereinbelow as the “coupled plate”.

As further shown in FIG. 3, the supported plate 12 can be arranged onto a pressure sensor 6, which is mounted onto the base plate 11. The pressure sensor 6 comprises a sensor member configured to measure a downward compression force applied onto its sensor surface. Preferably the pressure sensor is a load cell, which is a type of force sensor that, when connected to appropriate electronics, is configured for returning a signal proportional to the mechanical force applied to the system. Since supported plate is loosely arranged, it can move freely along the length of the rods. Accordingly, the sensor member 61 is directed upwards towards the underside of the supported plate 12 such that said plate 12 can be supported by said sensor member 61, when the pressure sensor 6 is mounted between the base plate 11 and supported plate 12.

The person skilled in the art appreciates that there are different configurations to realise a loose arrangement of a moveable plate. In some embodiments the loosely moveable plate may comprise apertures with a diameter large enough to avoid contacting the rod. In another embodiment the moveable plate may comprise a bearing, that provides a barrier between the plate and the rod, for example, a bushing with a brass friction cylinder. Additional lining or coating may be added to reduce friction between the moving plate and the rod. Alternatively or in combination, a rod may comprise a nonthreaded portion, with an advantageously smooth surface or other friction reducing means, such that when the rod rotates it does not interact with the loosely moveable plate. The nonthreaded portion advantageously is limited to a part of the fixture where movement of the loosely moveable plate is considered.

As further shown in FIG. 3, the coupled plate 13 can be coupled to the rods 2 such that it remains in place. This coupling is achieved by providing threaded apertures in said plate 13 that couple to a threaded portion of the rods 2, which is complementary to the threaded aperture of moveable plate. Accordingly, rotating the rods will cause said plate 13 to move, upward or downward, depending on the rotational direction and the threading. For example, a clockwise rotation may cause the plate 13 to move downwards, towards the other moveable plate 12, whereas a counterclockwise rotation will cause the plate 13 to move back upwards, away from plate 12, or the other way around, depending on the threading.

Since the supported plate 12 rests on the pressure member 61, and the cell 4 is mounted thereon, therefore, the forces measured by pressure sensor 6 represent the pressure applied onto the surface of the cell 4 by the moveable plates 12-13, specifically, by coupled plate 13 when it presses down against the supported plate 12 with the cell 4 clamped in between. Moreover, by adjusting the position of moveable plate 13 relative to plate 12, a range of pressures can be applied onto the clamped cell 4, depending on the resistance of the pressure sensor 6. The applied pressure will not change unless the plate 13 is moved by rotating the rods 4 again, upwards or downwards. In order to release the electrochemical cell, therefore, the cell fixture 1 may need to be coupled back to the base station 9 to release the applied pressure by rotating the rods 4. Alternatively or in combination, an emergency release may be provided on the cell fixture that can release the fixed cell without use of the base station.

The person skilled in the art appreciates that there are different configurations to realise a threaded coupling of a moveable plate. In some embodiments at least a portion of the rods may be threaded, corresponding with the distance that the threaded moveable plate is to be moved. Limiting the length of the threaded portion may allow for an easy way to prevent the plate from moving past a certain cut-off point. Alternatively, one or more stop members may be provided to stop movement of the threaded moveable plate. In another embodiment the whole length of the rods may be threaded.

In some embodiments at least one plate may have a flat surface, preferably the entire plate is planar. This is advantageous for realising a homogenous pressure distribution. Alternatively or in combination, the surface of at least one plate may be adapted for mounting a cell thereon. For example, a plate may have a depression adapted for the cell geometry such that the cell or part thereof can be mounted into it and that lateral movement can be prevented.

In some embodiments at least one plate may be rectangular shaped, preferably with a square surface. Such geometry is advantageous for realising a homogenous pressure distribution. Advantageously at least two, preferably all plates have the same shape to reduce design complexity. The skilled person understands that other shapes, advantageously symmetrical, may be contemplated still. For example, a hexagonal shape, an octagonal shape, a circular shape, and so on.

In some embodiments at least one plate may be a metal plate or comprise a metal material or alloy, such as steel, aluminium, or other materials. Metal plates are preferred due to their high resistance to plastic deformation under tension when applying a compressive force. The skilled person appreciates that other rigid materials may be contemplated provided that they can sufficiently resist deformation under pressure.

An embodiment of the fixture is discussed with reference FIG. 4, which shows that the fixture 1 can comprise an electrode connector means 7 for electrically connecting with the electrodes of the cell 4. A cell may commonly comprise a negative electrode and a positive electrode, which output can be measured for electrical characterisation of the clamped cell 4. However, once the clamping plates are fixed in place, access to the electrodes and/or cell tabs may be obstructed, making it more difficult to establish an electrical connection. On the other hand, mounting the connections beforehand is less convenient because the connection may shift or get damaged when compressive pressure is applied onto the cell 4.

FIG. 4 further shows that the electrode connector means 7 can be pre-mounted onto at least one of the moveable plates, preferably the coupled plate 13, in such a way that an electrical connection is established by clamping the cell 4 between the plates 12-13. Specifically, the electrode connector means 7 may comprise a pair of contact pins 71, arranged on one side of a moveable plate for electrically contacting the electrodes and/or tabs of the clamped cell 4, and a pair of connectors 72, arranged on the opposite side of said moveable plate, that are electrically connected to said contact pins. The electrode connector means 7 will move together with the moveable plate 13 when it is moved towards the cell 4. Advantageously, the contact pins comprise or are made from an electrically conductive material, for example, gold plated pins.

In some embodiments, the pair of contact pins have a contact distance between them that is adjustable to match the dimension of the electrodes and/or cell tabs. For example, the pair of contact pins can be adjustable in a direction defined along the length of the moveable plate that the electrode connector means is arranged on, so that the interelectrode distance between the contact pins can be adjusted to match the distance between the electrodes and/or tabs of the clamped cell. In another example, contact surface of the pair of contact pins can be adjustable in a direction defined relative to the moveable plate that the electrochemical cell can be mounted on, such that the distance between from the contact pins to the electrodes and/or tabs of the clamped cell can be adjusted to establish a connection. Although the latter examples are described separately, it is understood that they can also be combined.

In some embodiments the contact pins may be biased away from the moveable plate by a biasing member, such as a spring. Advantageously the contact pins may be oriented downwards, extending perpendicularly from the threaded moveable plate 13 towards the cell 4 mounted on the supported plate 12. This embodiment allows the electrical connection to be easily established and maintained even when the pressure is adjusted by moving the moveable plate 13.

In some embodiments the connectors may comprise a banana jack connectors and/or advantageously universal plugs. This allows the connection to be freely connected to various electrical connectors during electrical characterisation. The skilled person understands that any type of connector can be implemented since the connecting portion of the electrode connector means 7 can be easily customised. The connectors may be connected to the connector pins via an electrical connection running along a surface of the plate or a hole provided in the plate.

As shown in FIG. 4, the moveable plates 12-13 may comprise an electrically insulating coating cover 5, arranged on the surface facing the mounted cell 4. Specifically, an upper surface of the middle plate 12 and a lower surface of the upper plate 13. This pair of opposing covers 5 allows the cell 4 to be electrically insulated from the plates such that interference or other faulty conditions can be prevented, for example, a short circuit.

In some embodiments at least one plate may be covered by an electrically insulating coating or comprise an electrically insulating material mounted thereon, such as a polyether ether ketone (PEEK). This is particularly advantageous if a steel plate comprises a metal in order to avoid any electrical interaction. Various electrically insulating material may be contemplated provided that they can sufficiently resist deformation under pressure.

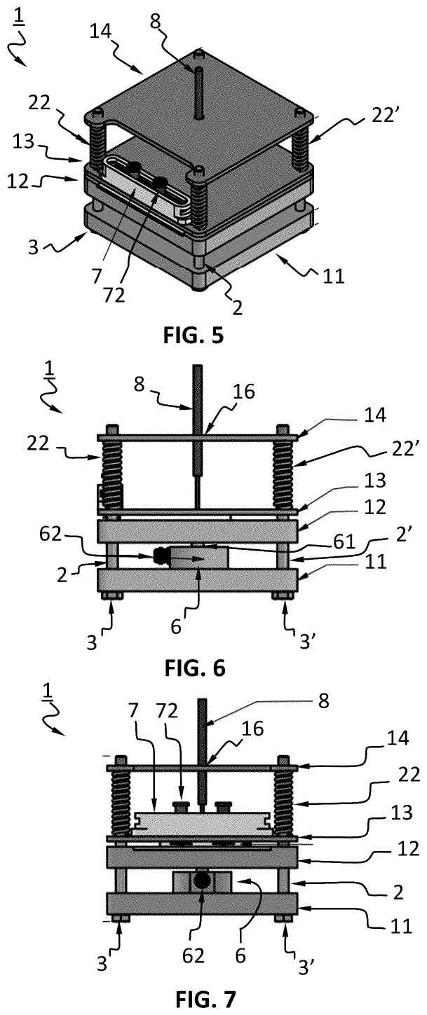

Another embodiment of the cell fixture is discussed below with reference to FIG. 5, which shows that the cell fixture can comprise an expansion sensor means configured for measuring an expansion of the cell. Measurement of cell expansion under compressive pressure can be used for cell characterisation. However, measurement of the cell's thickness may be difficult once the clamping plates are fixed in place because the cell 4 is advantageously mounted centrally on the plate and hence measurements of the cell's thickness is obstructed.

FIG. 5 shows that the cell fixture 1 may comprise a second fixed plate 14, arranged in parallel relation to the base plate 11. The second fixed plate 14 is configured for securing of the expansion sensor means, which is mounted in an aperture 16 provided in the centre of said plate 14. Preferably the fixed plate 14 is arranged at an opposite end of the plurality of rods 2, such that the moveable plates 12-13 are arranged between the base plate 11 and said fixed plate 14. This allows for mounting the pressure sensor and expansion sensor on opposite sides of the cell.

The fixed plate 14 may be fixed using techniques known in the art. FIG. 5 shows that the plate 14 may be biased away from the moveable plates by means of four biasing members 22, such as springs, arranged around each rod 2. Preferably the biasing members are arranged such as to be blocked by the apertures 15 and not pass through the vertical channels when the rods 2 are inserted therein. Preferably, the plate is fixed without fasteners such that it cannot be loosened when the moveable plates are moved. Advantageously, the fixture may comprise a friction reducing means arranged between the fixed plate and the rods such that friction is reduced when the rod is rotated. For example, the friction reducing means may comprise a roll bearing arranged at an aperture of said plate.

As shown in FIG. 6, the expansion sensor may comprise an elongated displacement sensor configured to measure a displacement of a surface of the mounted cell 4 relative to the fixed plate 14. The displacement sensor may measure the distance (e.g. in mm or μm) between the plates. Since the position of plate 14 is fixed, it can form a reference point for the displacement sensor to measure relative displacement for cell thickness measurements. Hence, by measuring a plurality of distances, including a first measurement corresponding with the cell's thickness when initially clamped, and a second measurement corresponding with the cell's thickness at a set time after clamping, the expansion of the cell can be determined based on a difference in displacement based on said measurement. Accordingly, by adding more measurements the cell expansion's rate can be tracked over time. Additionally, different testing conditions can be applied to the cell while still tracking its expansion's rate.

As previously discussed, the cell fixture can be used in combination with a base station, which is configured to couple to said cell fixture when mounted thereon and rotate the rods such that it causes at least one moveable plate to move relative to the other moveable plate, thereby applying a clamping force onto the cell mounted between them.

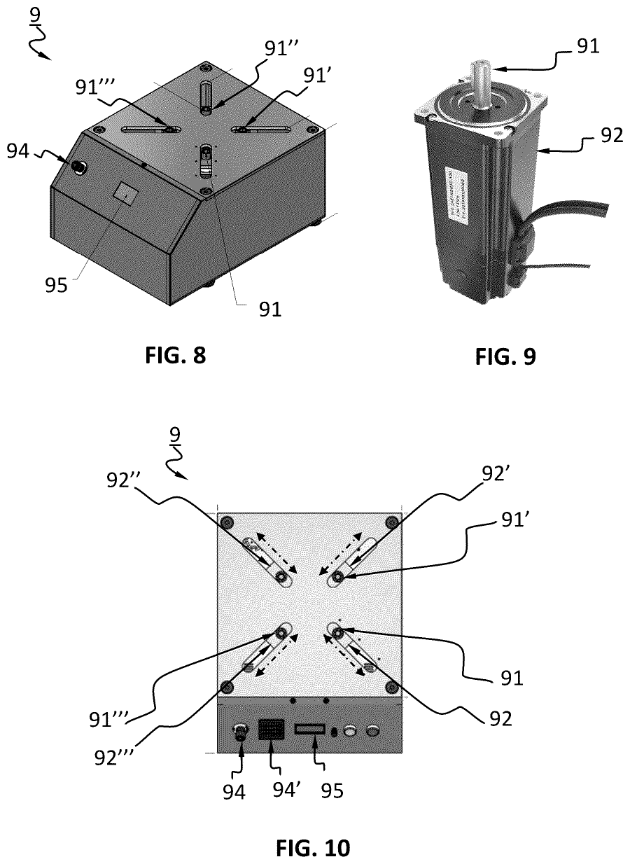

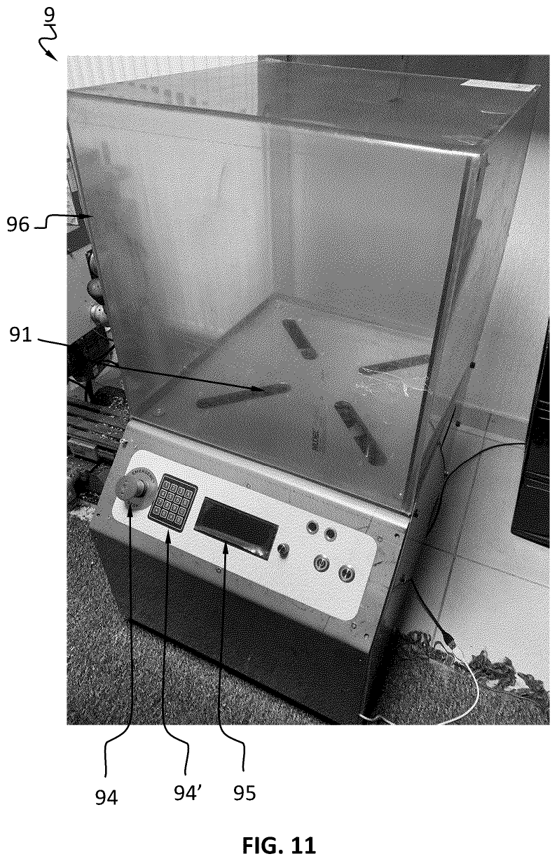

An embodiment of the base station 9 is discussed with reference to FIG. 8, which shows the station 9 comprising four actuators 91 arranged in parallel relation to each other. The actuators 91 extend from the base station 9 such that they can couple with the four coupling members 4 arranged on the underside of the cell fixture 1, for example as shown in FIG. 4, which may comprise a receptacle that at least a portion of the actuator can be inserted into. The skilled person, however, appreciates that the coupling between the coupling member and actuator can be reversed by having the coupling member extend from the fixture and the actuator comprise a receptacle. Nonetheless, the former embodiment allows for easier use and mounting.

In some embodiments the coupling member may comprise a tapered receptacle with a fitting that matches the outside diameter of the actuator such that a reliably coupling is realised. For example, the actuator may comprise one or more shapes provides along the exterior, such as vertical grooves and/or projections, that match the corresponding shapes provided along the interior of the coupling member. Advantageously, the tapered receptacle is configured such that it guides the inserted member along the fitting to allow or easier coupling.

In some embodiments the coupling member may be incorporated into the rotatable rod or form part thereof. This allows for a more reliable coupling. Preferably the coupling member and rod are part of a single component. For example, the rod may comprise a screw whereby the coupling member forms the screw head, or the rod may comprise a bolt whereby the coupling member forms the bolt head, and the like.

Once coupled, the actuators can be rotated by one or more motors. FIG. 9 shows an exemplary motor 92 with an upwards oriented actuator 91 such that it could suitably fit into the base station 9 of FIG. 8. Such an embodiment would allow the rods to be actuated through a direct connection between the motor and the coupling member. Specifically, four such motors may be arranged in parallel relation to each other, corresponding with the positioning of the coupling members of the fixture.

In another embodiment the base station may comprise at least one motor configured for actuating one or more actuators, simultaneously or independently. The motor may be connected to the actuators via one or more intermediate components, such as gears, such that the rods can be actuated with a single motor. The motor may be a linear or rotational motor. Such an embodiment would provide for a simultaneous rotation of the rods. Advantageously, the actuators are operatively connected such that their rotation is synchronised to ensure a more homogeneous pressure distribution.

In another embodiment the base station may comprise at least one motor per actuator or group of actuators, configured for actuating said actuators, simultaneously or independently. Such an embodiment is advantageous because it allows controlling a single actuator independently to adjust a local pressure difference, for example to correct a pressure difference in a specific corners in case some adjustments specific to a side would be required. Moreover, the force produced by an actuator driven by a dedicated motor can typically exceed that of multiple actuators driven by a shared motor, which could allow for applying a greater force onto the cell or improved control of the applied force. Advantageously the motors are operatively connected such that their rotation is synchronised to realise a more homogeneous pressure distribution.

In some embodiments the base station may comprise a stepper motor configured for rotating at least one rod in a number of predefined steps, specifically, by dividing a full rod rotation into a number of equal steps. Preferably the stepper motor is configured for dividing a full rod rotation into steps of 5 nm or less per step of linear displacement allowing a precisely adjust and automatically control of the mechanical force. Advantages of stepper motors are low cost, high reliability, high torque at low speeds and a simple, rugged construction that operates in almost any environment. This embodiment allows for controlling the compressive pressure applied onto the cell in rotational steps.

In an embodiment, the station may comprise a high-resolution servo drive for force regulation. This allows for high positioning speeds with a minimum step width of 5 nm or less, which increases the accuracy when compared to hydraulic systems of the art. Additionally, the mechanical force may be automatically regulated by a closed loop control system using a microcontroller to apply a homogeneous pressure distribution on the surface of the test cell, as described further below.

A further embodiment of the base station is discussed with reference to FIG. 10, which shows that the actuators 91 and/or motors 92 may be moveably arranged such that their position can be adjusted along at least one axis of movement—indicated by the double-sided arrows. As shown, the actuator 91 may be moved diagonally, inwards or outwards, along a top surface of the base station 9, simultaneously or independently, such that the position of said actuator 91 can be aligned with a corresponding coupling member 4 when mounted thereon. Advantageously the plurality of actuators 91 and/or motors 92 is moveably coupled such that they move simultaneously along the surface of the base station, preferably in opposite directions, for example diagonally inwards or outwards. This embodiment allows for controlling the compressive pressure applied onto the cell in rotational steps. Another example is shown in FIG. 1, in which the position of an actuator 9 is adapted to the dimensions of the cell fixture 1.

An embodiment wherein actuators and/or motors are moveably arranged allows for setting the station's mounting dimensions based on the dimension of the cell fixture. Accordingly, this provides the possibility to use cell fixtures of different dimensions without needing to change the base station. For example, when a cell fixture with a smaller dimension is utilised the actuators and/or motors can be moved inwards, whereas when a cell with a larger dimension is utilised the actuators and/or motors can be moved outwards. This further reduces the cost of the assembly and allows a combining a single base station with an unlimited number of fixtures.

In this way, the cell fixture can be adapted depending on the application, for example, based on the dimension and number of electrochemical cells that will be mounted thereon. For example, the dimensions of the cell fixture can be adapted to match that of the cells, but also the electrode connector means, specifically to match the position of the electrodes and/or tabs, the footprint for mounting of cells, and so on. The adaptability of the base station may, therefore, be appreciated in that the same base station can be shared for a variety of different cell fixtures, with the same or different configurations. As such, the configuration of the cell fixture can be easily adapted at any stage during testing, for example, to match a different type of electrochemical cell. Hence, this makes the assembly particularly flexible for testing of different types of electrochemical cells in a variety of applications and testing conditions, for instance, in research and development environments.

In some embodiments the base station may be configured for automated or semi-automated adjustments of the mounting dimensions. An exemplary semi-automated embodiment may comprise an actuator configured for adjusting the position of the actuators and/or motors, for example linearly, when the user presses a button or enter the fixture dimensions via a user input panel. An exemplary semi-automated automated embodiment may comprise a sensor configured for detecting the dimensions of the fixture and automatically adjusting the position of the actuators and/or motors to a corresponding value. The fixture may be, for example provided with a scannable code provided on the underside which contains the corresponding dimensions.

As further shown in FIG. 10, the base station may comprise tools for user interaction. For example, it may provide one or more user input units, such as manual input 94′ to receive a selected pressure value or an emergency stop button 94, and one or more display units 95 configured for displaying various parameters, such as the measured/to be applied compressive pressure. The stop button 94 may, for example, stop the operation of the motors 92. Alternatively or in combination, any pressure applied onto the coupled fixture 1 can be released. The skilled person appreciates that the base station may be customised further to improve the user interactivity using devices known in the art, such as plug-in units to readouts various values or other components.

In some embodiments the base station may comprise a control unit configured for receiving pressure sensing data from the pressure sensor means of the cell fixture. The sensing data may be transferred via a wired or wireless connection. For example, as shown in FIG. 3, the pressure sensing means 6 may comprise a sensor connector socket 62 configured for connecting with a plug to read-out sensing data therefrom. Accordingly, the base station 9 may comprise a cable or another form of connection means that can be plugged into the sensor connector socket 62. Data from the pressure sensing means 6 can then be transferred to the base station 9 for further processing (e.g. as input). For example, the measure pressure data can be displayed onto the display unit 95 of the base station 9 shown in FIG. 8.

In some embodiments the base station may comprise a control unit configured for controlling the actuation of the actuator in order to apply a pressure onto the mounted cell based on sensing data from the pressure sensing means. Advantageously, the base station receives near real-time data from the pressure sensor such that it can make accurate adjustment if necessary. This allows for automating the pressure setting by implementing a feedback loop whereby the base station increases the pressure applied onto the mounted cell until a set value is reached and optionally reduces the pressure if the set value is exceeded. Alternatively, the station may be configured for gradually increasing the pressure based on direct user control such that (minor) manual adjustments of the pressure are still possible.

In some embodiments the base station may comprise a control unit configured for receiving pressure sensing data from the pressure sensor means of the cell fixture. The sensing data may be transferred via a wired or wireless connection. Other computing devices can also be coupled to the control unit, such as a personal device that (automatically) track of all the implemented parameters on the cell, such as a lab diary.

In some embodiments the base station may comprise a protective shield to protect a user of the assembly during operation. For instance, when (excessive) pressure is applied onto the fixed cell, there is a risk of accidental explosion, for example, due to excessive pressure build on the cell that could cause the cell itself or parts of the fixture to be discharged. There exist different types of shield that can be implemented into the assembly.

For example, an embodiment of the base station 9 is shown in FIG. 8 that comprises a transparent cover 96 arranged on top of the station 9, with at least one moveable wall, such as a door, that allows entry into the interior space. The cover may be, for example, a plastic material such as Plexiglas. Advantageously, the station can be configured to detect the locked state of the door and blocks any operation of the base station if the door is unlocked, for instance, by blocking rotation of any of the actuators. For example, the door locking mechanism may comprise a sensor that detects if the door is locked or not, and optionally transmits the locking state to the base station.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment.

As used herein, the terms “comprising”, “comprises” and “comprised of” as used herein are synonymous with “including”, “includes” or “containing”, “contains”, and are inclusive or open-ended and do not exclude additional, non-recited members, elements or method steps. The terms “comprising”, “comprises” and “comprised of” when referring to recited members, elements or method steps also include embodiments which “consist of” said recited members, elements or method steps. The singular forms “a”, “an”, and “the” include both singular and plural referents unless the context clearly dictates otherwise.

As used herein, relative terms, such as “left,” “right,” “front,” “back,” “top,” “bottom,” “over,” “under,” etc., are used for descriptive purposes and not necessarily for describing permanent relative positions. It is to be understood that such terms are interchangeable under appropriate circumstances and that the embodiment as described herein are capable of operation in other orientations than those illustrated or described herein unless the context clearly dictates otherwise.

Objects described herein as being “adjacent” to each other reflect a spatial relationship between the described objects, that is, the term indicates the described objects must be arranged in a way to perform a designated function which include a direct (i.e. physical) or indirect (i.e. close to or near) physical contact, as appropriate for the context in which the phrase is used.

Objects described herein as being “connected” or “coupled” reflect a functional relationship between the described objects, that is, the terms indicate the described objects must be connected in a way to perform a designated function which may include a direct or indirect connection in an electrical or nonelectrical (i.e. physical) manner, as appropriate for the context in which the term is used.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result.

As used herein, the term “about” is used to provide flexibility to a numerical value or range endpoint by providing that a given value may be “a little above” or “a little below” said value or endpoint, depending on the specific context. Unless otherwise stated, use of the term “about” in accordance with a specific number or numerical range should also be understood to provide support for such numerical terms or range without the term “about”. For example, the recitation of “about 30” should be construed as not only providing support for values a little above and a little below 30, but also for the actual numerical value of 30 as well.

The recitation of numerical ranges by endpoints includes all numbers and fractions subsumed within the respective ranges, as well as the recited endpoints. Furthermore, the terms first, second, third and the like in the description and in the claims, are used for distinguishing between similar elements and not necessarily for describing a sequential or chronological order, unless specified. It is to be understood that the terms so used are interchangeable under appropriate circumstances and that the embodiments of the invention described herein are capable of operation in other sequences than described or illustrated herein.

Reference in this specification may be made to devices, structures, systems, or methods that provide “improved” performance (e.g. increased or decreased results, depending on the context). It is to be understood that unless otherwise stated, such “improvement” is a measure of a benefit obtained based on a comparison to devices, structures, systems or methods in the prior art. Furthermore, it is to be understood that the degree of improved performance may vary between disclosed embodiments and that no equality or consistency in the amount, degree, or realization of improved performance is to be assumed as universally applicable.

### EXAMPLES

Examples of an implementation of the technology according to the present invention is given hereinbelow. The provision of examples is meant to aid the reader in understanding the technological concepts more easily, but it is not meant to identify the most important or essential features thereof, nor is it meant to limit the scope of the present invention.

### Example 1

Since it is an objective of the present cell fixture to study electrochemical characterizations as function of pressure, therefore, it may be necessary to apply a range of different pressures. However, the accuracy of a pressure sensing devices, such as load cells, typically depends on a percentage of the total measuring range. Thus, it is generally less accurate to use a large load cell (e.g., 80 kN) to apply a low force.

Accordingly, different embodiment of cell fixtures may be considered based on the configuration of the pressure sensing means and the fixture dimensions (e.g., width, length, thickness of the plates and rods, etc.). For instance, a smaller fixture can be used to apply a low force (e.g., in range from 0.001 kN up to 1 kN), and a larger fixture can be used to apply high force (e.g., up to 80 kN). This concept can ensure the highest level of accuracy during measurements, even when applying different ranges of pressure.

Further to the above, Table 1 provides several exemplary cell fixtures along with their respective force and corresponding pressure ranges applicable to cells mounted on them. These reported values have been determined through calibration using two load sensors, specifically a strain-gage Wheatstone bridge (model: 8524), capable of measuring forces in the range of 0-1 kN and 0-80 kN, with an accuracy of 0.1%. The measurements were conducted within an operational temperature range spanning from −30° C. to +120° C.

In the present Example, the base station employed for applying force is equipped with four stepper motors that convert electrical signals into mechanical shaft rotation. As the digital pulses increase in frequency, the step movement transitions into continuous rotation, and the rotational speed is directly proportional to the pulse frequency. Each revolution of the motor is divided into 512,000 steps, with the microcontroller sending a pulse for each step. This design enables precise positioning at high speeds, with a minimum step size of 3.42 nm.”

Table 1 provides an overview of exemplary cell fixture embodiments along with the tested range of force and pressure applicable to cells mounted on them. It can be generally observed that smaller dimension cell fixtures tend to enable testing at higher maximum force and pressure levels. Conversely, larger dimension cell fixtures typically allow for testing at lower minimum force and pressure levels. Therefore, the choice of an appropriate cell fixture dimension depends on factors such as the dimensions and quantity of mounted cells (e.g., stacked configurations) and the specific force and pressure to be applied to one or more cells. It's important to note that the reported values are illustrative and not intended to restrict the scope of the teachings and applications presented in this disclosure.

TABLE 1
Exemplary embodiments of cell fixtures

| Cell fixture | Force range | | Pressure range | | | | | |
|---|---|---|---|---|---|---|---|---|
| dimension | kN | | MPa | | Bar | | Ton/m² | |
| (cm²) | Min | Max | Min | Max | Min | Max | Min | Max |
| 1 × 1 | 0.001 | 80 | 0.01 | 800 | 0.1 | 8000 | 1.02 | 81577.30 |
| 3 × 4.5 | 0.001 | 80 | 0.00074 | 59.26 | 0.0074 | 592.59 | 0.075 | 6042.84 |
| 8 × 10 | 0.001 | 80 | 0.000125 | 10 | 0.001250 | 100 | 0.0127 | 1019.72 |
| 13 × 17 | 0.001 | 80 | 0.000045 | 3.62 | 0.000452 | 36.20 | 0.00453 | 369.13 |

| Cell fixture | Force range | Pressure range (continued) | |
|---|---|---|---|
| dimension | kN | Pound/inch² (psi) | Atmosphere |

| (cm²) | Min | Max | Min | Max | Min | Max |
|---|---|---|---|---|---|---|
| 1 × 1 | 0.001 | 80 | 1.45 | 116030.19 | 0.099 | 7895.39 |
| 3 × 4.5 | 0.001 | 80 | 0.107 | 8594.83 | 0.0073 | 584.84 |
| 8 × 10 | 0.001 | 80 | 0.018 | 1450.374 | 0.00123 | 98.69 |
| 13 × 17 | 0.001 | 80 | 0.00656 | 525.022 | 0.00044 | 35.73 |

Table 1 shows that cell fixture's adaptability extends to testing a broader range of minimum and maximum force and pressure levels. This adaptability can be achieved by modifying the pressure sensor or adjusting the cell fixture's dimensions. For instance, it's feasible to manufacture a larger cell fixture capable of applying even higher pressures.

In conclusion, these exemplary embodiments showcase the heightened accuracy and extended range of testable force and pressure levels compared to conventional practices. Notably, the minimum applicable force of 0.001 N underscores the remarkable precision offered by the technology of the present disclosure in contrast to conventional methods.

### Example 2

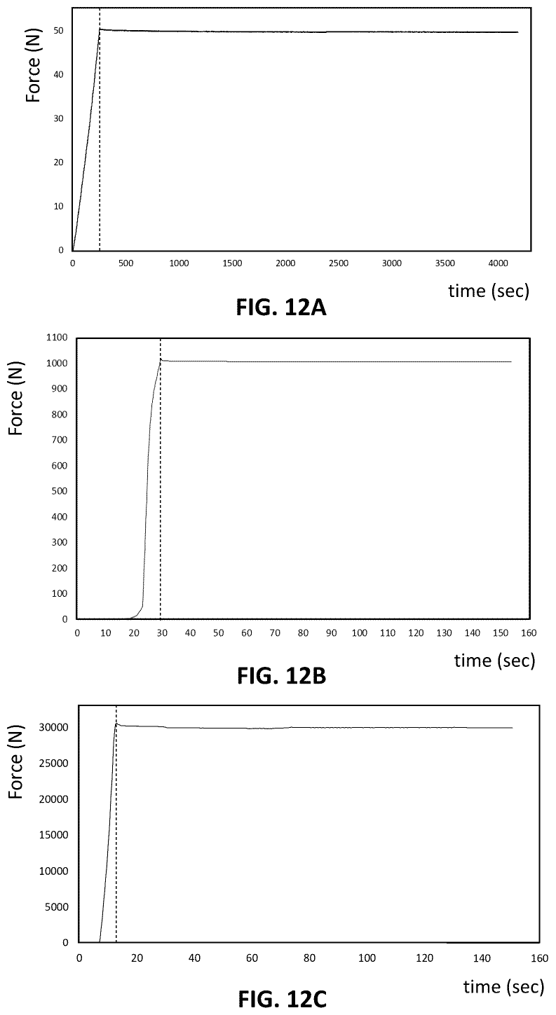

In continuation of Example 1, the stability of the applied pressure within exemplary cell fixtures was tested over time within three different pressure ranges. Maintaining stable pressure is crucial for assessing the impact of various testing conditions on the clamped cell or cells. To conduct this test, a reference electrochemical cell was affixed onto a cell fixture measuring 18×18 cm², using the same configuration as described in Example 1. Three distinct pressure levels were applied utilizing the base station, specifically 50.0 N, 1,000 N, and 30,000 N. Once these specified pressures were attained, the cell fixture was released from the base station, and changes in pressure were continuously monitored for a predetermined duration (with the sensor connected to a read-out unit). The outcomes are discussed below, with reference to FIG. 12A-12C.

FIG. 12A presents the results for the low-pressure setting of ±50 N. The graph illustrates that the applied pressure initially peaks at 50.0 N, and following fixture release, it gradually decreases to approximately 49.8 N. Subsequently, it remains stable within a ±0.2 N error margin (below 0.1% measurement error) throughout the entire 45 000 seconds measurement period.

FIG. 12B presents the results for the medium-pressure setting of ±1 000 N. The graph demonstrates that the applied pressure initially peaks at 1,010 N, and after the fixture release, it gradually decreases to around 1,006 N. Subsequently, it maintains stability within a ±0.5 N error margin (below 0.1% measurement error) during the entire 155-second measurement time.

FIG. 12C presents the results for the high-pressure setting of ±30 000 N. The graph reveals that the applied pressure initially peaks at 30,150 N and subsequently decreases after fixture release, stabilizing at approximately 30 000 N. It remains within a ±50 N error margin (approximately 0.2% error) during the entire 155-second measurement time.

In conclusion, the aforementioned experiments demonstrate that the cell fixture maintains a highly stable pressure profile after release from the base station, even under varying levels of applied pressure, over an extended period of time.

1. Cell fixture assembly (100) for applying and maintaining a compressive pressure on one or more electrochemical cells (4); wherein the cell fixture assembly (100) comprises at least one cell fixture (1) and a base station (9);
wherein the cell fixture (1) comprises:
at least one fixed base plate (11);
at least two moveable plates (12,13) arranged parallel to the base plate (11); whereby the moveable plates (12,13) have oppositely arranged surfaces for contacting the electrochemical cell (4) mounted between them; whereby the fixed and moveable plates (11-13) comprise a plurality of apertures (15) that are at least partially aligned to create a plurality of vertical channels that extend through said plates (11-13);
a pressure sensor means (6), disposed between the base plate (11) and at least one of the moveable plates (12), comprising a sensor member (61) arranged to support said moveable plate (12), and configured for measuring a pressure applied to the electrochemical cells (4);
a plurality of rotatable rods (2), insertable in the plurality of vertical channels, that are configured to rotatably couple with at least one of the moveable plates (13); whereby a rotation of the plurality of rotatable rods (2) causes one of the moveable plates (13) to move relative to the other moveable plate (12), thereby applying or releasing compressive pressure on the electrochemical cell (4) mounted between them; and,
a plurality of coupling members (3) in connection with the plurality of rotatable rods (2);
wherein the base station (9) comprises:
a plurality of actuators (91) configured for releasably coupling with the plurality of coupling members (3) of the cell fixture (1), and for inducing the rotation of the rotatable rods (2), and
at least one motor (92) configured for driving the actuators (91).

2. The cell fixture assembly (100) according to claim 1, whereby the apertures (15) of at least one moveable plate (13) are threaded, and the plurality of rotatable rods (2) have a threaded portion with a threading that is complementary to the threaded apertures (15) of the moveable plate (13).

3. The cell fixture assembly (100) according to any one of the preceding claims, wherein the coupling member (3) comprises a receptacle with a fitting that matches an actuator (91) of the base station (9) such that at least a portion of the actuator (91) can be inserted into the coupling member (3).

4. The cell fixture assembly (100) according to any one of the preceding claims, wherein the coupling member (3) is arranged on an end of the rotatable rod (2) extending from the base plate (11).

5. The cell fixture assembly (100) according to any one of the preceding claims, further comprising an electrode connector means (7) that comprises a pair of electrical contacts (71), arranged on one side of a moveable plate, that are configured for electrically contacting the electrodes (2) of the one or more cells, and a pair of electrical connectors (72), arranged on the opposite side of said moveable plate, that are electrically connected to the electrical contacts (71).

6. The cell fixture assembly (100) according to any one of the preceding claims, further comprising an expansion sensor means configured for measuring an expansion of the one or more cells in at least one direction;
preferably wherein the expansion sensor means comprises a displacement sensor configured for measuring a distance between at least one moveable plate and at least one fixed plate.

7. The cell fixture assembly (100) according to any one of the preceding claims, further comprising a second fixed plate (14) arranged parallel to the base plate (11) at an opposite end of the plurality of rods (2); and a biasing member configured for biasing the second fixed plate (14) away from at least one of the moveable plates such that the second fixed plate (14) remains in a fixed position relative thereto; and an expansion sensor means (8) configured for measuring a distance between the second fixed plate (14) and said moveable plate.

8. The cell fixture assembly (100) according to claim 7, whereby the expansion sensor means (8) comprises a displacement sensor, disposed between the second fixed plate (14) and the moveable plate; preferably mounted in an aperture (16) provided in the second fixed plate (14).

9. The cell fixture assembly (100) according to any one of the preceding claims, wherein the cell fixture (1) is mountable on the base station (9) such that it can freely switch between a coupled state and a released state without altering the compressive pressure applied onto the one or more cells (4).

10. The cell fixture assembly (100) according to any one of the preceding claims, whereby the base station (9) comprises a plurality of motors (92) configured for independently driving one or more of the actuators (91).

11. The cell fixture assembly (100) according to any one of the preceding claims, whereby the motor (92) comprises a stepper motor configured for rotating at least one rotatable rod (2) in a set number of predefined steps;
preferably by dividing a 360 degrees rotation of the rotatable rod (2) into steps of 5 nm or less, for example, 4 nm, 3 nm, 2 nm, or 1 nm.

12. The cell fixture assembly (100) according to any one of the preceding claims, whereby the plurality of actuators (91) and/or motors (92) are moveably arranged within the base station (9) such that their positions can be adjusted along at least one axis of movement to match the position of a corresponding coupling member (3) of the cell fixture (1)

13. The cell fixture assembly (100) according to claim 12, wherein the positions of the plurality of actuators (91) and/or motors (92) within the base station (9) can be adjusted to match the dimension of the cell fixture (1).

14. The cell fixture assembly (100) according to any one of claim 12 or 13, whereby the plurality of actuators (91) and/or motors (92) are moveably coupled such that their positions within the base station (9) can be adjusted simultaneously;
preferably by moving the plurality of actuators (91) and/or motors (92) in opposite directions within the base station (9).

15. The cell fixture assembly (100) according to any one of the preceding claims, whereby the base station (9) further comprises a control unit communicatively connected to the pressure sensor means (6) to receive pressure sensing data therefrom; whereby the control unit is operatively connected to the motor (92) and configured to control the actuation of at least one actuator (91) based on the pressure sensing data;
preferably applying or releasing pressure to the one or more cells (4) until it matches a user input.

16. The cell fixture assembly (100) according to any one of the preceding claims, whereby a plurality of electrochemical cells are stacked on top of each other between the opposing surfaces of the moveable plates.

17. Cell fixture (1) for use in combination with a base station (9) of the cell fixture assembly (100) according to any one of the preceding claims;
wherein the cell fixture (1) comprises:
at least one fixed base plate (11);
at least two moveable plates (12,13) arranged parallel to the base plate (11); whereby the moveable plates (12,13) have oppositely arranged surfaces for contacting the electrochemical cell (4) mounted between them; whereby the fixed and moveable plates (11-13) comprise a plurality of apertures (15) that are at least partially aligned to create a plurality of vertical channels that extend through said plates (11-13);
a pressure sensor means (6), disposed between the base plate (11) and at least one of the moveable plates (12), comprising a sensor member (61) arranged to support said moveable plate (12), and configured for measuring a pressure applied to the electrochemical cell (4);
a plurality of rotatable rods (2), insertable in the plurality of vertical channels, that are configured to rotatably couple with at least one of the moveable plates (13); whereby a rotation of the plurality of rotatable rods (2) causes one of the moveable plates (13) to move relative to the other moveable plate (12), thereby applying or releasing compressive pressure on the electrochemical cell (4) mounted between them; and,
a plurality of coupling members (3) in connection with the plurality of rotatable rods (2), that are configured for releasably coupling with a plurality of rotatable rods (2) of the base station (9).

18. Base station (9) for use in combination with one or more cell fixtures (1) of the cell fixture assembly (100) according to any one of the preceding claims;
wherein the base station (9) comprises:
a plurality of actuators (91) configured for releasably coupling with a plurality of coupling members (3) of the cell fixture (1), and for inducing the rotation of the rotatable rods (2), and
at least one motor (92) configured for driving the actuators (91).

19. Method for applying and maintaining of a compressive pressure on one or more electrochemical cells (4) using the fixture assembly (100) according to any one of the preceding claims;
the method comprising the steps of
mounting a cell fixture (1) onto a base station (9) by releasably coupling a plurality of coupling members (3) of the cell fixture (1) to a plurality of actuators (91) of the base station (9);
mounting the electrochemical cell (4) on a moveable plate of the cell fixture (1);
driving an actuator (91) of the base station (9) to induce a rotation of a plurality of rods (2) of the cell fixture (1) such that at least one moveable plate moves towards another moveable plate, thereby applying or releasing compressive pressure on the one or more cells (4) mounted between them;
releasing the cell fixture (1) from said base station (9) without altering the compressive pressure applied on the electrochemical cell (4).

20. The method according to claim 19, whereby a plurality of electrochemical cells are stacked on top of each other on the moveable plate of the cell fixture (1).
